(19) United States
(12) Patent Application Publication
(10) Pub. No.: US 2025/0259892 A1
(43) Pub. Date: Aug. 14, 2025

(54) SEMICONDUCTOR DEVICE MANUFACTURING METHOD AND SEMICONDUCTOR DEVICE

(71) Applicant: Kioxia Corporation, Tokyo (JP)

(72) Inventors: Yimin LIU, Yokkaichi (JP); Toshiyuki MORITA, Yokkaichi (JP); Daichi NISHIKAWA, Mie (JP); Akinori KIMURA, Yokkaichi (JP)

(73) Assignee: Kioxia Corporation, Tokyo (JP)

(21) Appl. No.: 18/830,280

(22) Filed: Sep. 10, 2024

(30) Foreign Application Priority Data
Feb. 8, 2024 (JP) 2024-018163

(51) Int. Cl. H01L 21/768; H01L 23/528; H01L 23/532

(52) U.S. Cl. CPC H01L 21/76876; H01L 21/76846; H01L 21/76877; H01L 23/5283; H01L 23/53257

(57) ABSTRACT

A semiconductor device manufacturing method according to the present embodiment includes forming a recessed part in a first insulating film. The present manufacturing method also includes forming a first conductive film containing a first metal on an inner side surface and a bottom surface of the recessed part. The present manufacturing method also includes forming an amorphous layer on the first conductive film. The present manufacturing method also includes forming a second conductive film containing the first metal on the amorphous layer.

### CROSS-REFERENCE TO RELATED APPLICATIONS

This application is based upon and claims the benefit of priority from the prior Japanese Patent Application No. 2024-018163, filed on Feb. 8, 2024, the entire contents of which are incorporated herein by reference.

### FIELD

The embodiments of the present invention relate to a semiconductor device manufacturing method and a semiconductor device.

### BACKGROUND

The resistance of a wire increases as the width of the wire decreases with miniaturization. It is desirable that the resistance of the wire is low.

### BRIEF DESCRIPTION OF THE DRAWINGS

FIG. 1A is a cross sectional view illustrating an example of a semiconductor device manufacturing method according to a first embodiment;

FIG. 1B is a cross sectional view illustrating an example of the semiconductor device manufacturing method, following FIG. 1A;

FIG. 1C is a cross sectional view illustrating an example of the semiconductor device manufacturing method, following FIG. 1B;

FIG. 1D is a cross sectional view illustrating an example of the semiconductor device manufacturing method, following FIG. 1C;

FIG. 2 is a graph illustrating an exemplary measurement result of the specific resistance of a conductive film according to the first embodiment;

FIG. 3 is a cross sectional view illustrating an example of the configuration of a wire according to a first comparative example;

FIG. 4 is a graph illustrating an exemplary measurement result of the specific resistance of the conductive film for further description of characteristics of an amorphous layer in the first embodiment; and

FIG. 5 is a cross sectional view illustrating an example of the structure of a semiconductor device according to a second embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device manufacturing method according to the present embodiment includes forming a recessed part in a first insulating film. The present manufacturing method also includes forming a first conductive film containing a first metal on an inner side surface and a bottom surface of the recessed part. The present manufacturing method also includes forming an amorphous layer on the first conductive film. The present manufacturing method also includes forming a second conductive film containing the first metal on the amorphous layer.

### First Embodiment

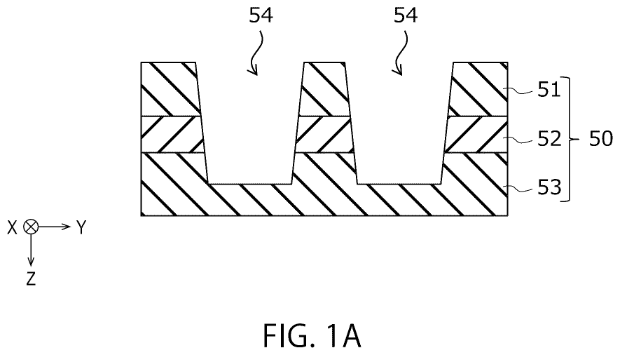

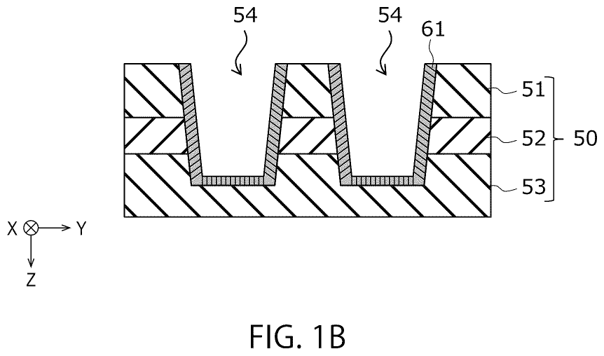

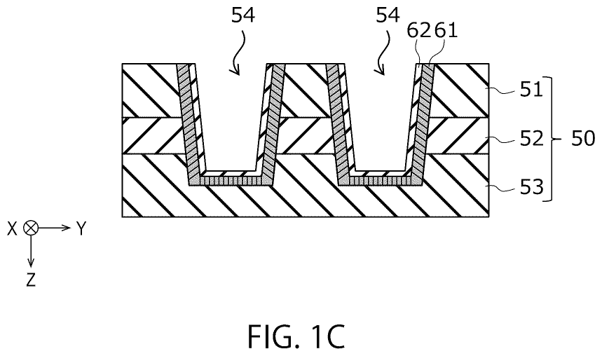

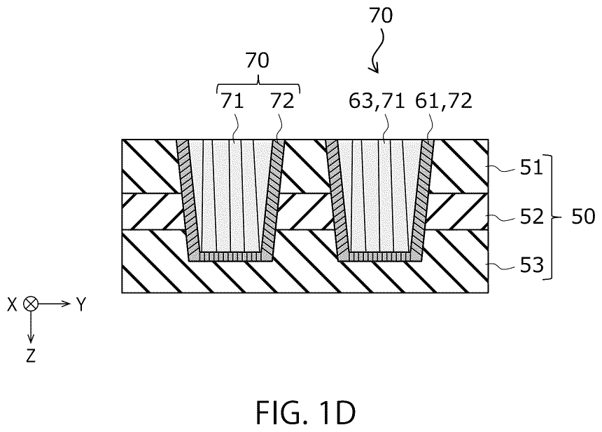

FIGS. 1A to 1D are cross sectional views illustrating an example of a semiconductor device manufacturing method according to a first embodiment. More specifically, FIGS. 1A to 1D are diagrams for description of formation of a wire 70 included in a semiconductor device.

The wire 70 illustrated in FIG. 1D is electrically connected to a non-illustrated semiconductor circuit. For example, the wire 70 extends in an X direction and a plurality of the wires 70 are disposed in a Y direction. The particle sizes of conductive films 61 and 63 (electric conductors 71 and 72) are schematically illustrated in FIGS. 1B to 1D.

First, as illustrated in FIG. 1A, recessed parts 54 are formed in an insulating film 50. In the example illustrated in FIG. 1A, the insulating film 50 includes stacked insulating films 51, 52, and 53. The insulating film 51 contains, for example, silicon oxide (SiO₂). The insulating film 52 contains, for example, silicon nitride (SiN). The insulating film 53 contains, for example, silicon oxide (SiO₂).

Subsequently, as illustrated in FIG. 1B, the conductive film 61 containing the first metal as a primary component is formed on the inner side surface and bottom surface of each recessed part 54. The first metal is, for example, tungsten (W). The conductive film 61 is, for example, a tungsten film formed by physical vapor deposition (PVD). The thickness of the conductive film 61 in a Z direction is, for example, 3 nm to 7 nm. The conductive film 61 has a relatively small particle size as illustrated in FIG. 1B. The particle size of the conductive film 61 will be described later.

Subsequently, as illustrated in FIG. 1C, an amorphous layer 62 is formed on the conductive film 61. The amorphous layer 62 contains the first metal and oxygen and is, for example, an oxide film layer containing tungsten oxide (WOₓ). The amorphous layer 62 is formed by, for example, oxidizing the surface of the conductive film 61. The amorphous layer 62 is thinner than the conductive film 61. The conductive film 61 preferably has a thickness, for example, equal to or larger than approximately 3 nm in the Z direction to ensure barrier properties. For example, in a case where the conductive film 61 is formed with a thickness of approximately 4 nm, the thickness of the amorphous layer 62 in the Z direction is approximately 1 nm.

The following description will be made with an assumption that the amorphous layer 62 is formed by natural oxidation. In this case, deposition of the conductive film 61 and deposition of the conductive film 63 to be described later are performed by different devices, respectively.

Subsequently, as illustrated in FIG. 1D, the conductive film 63 containing tungsten is formed on the amorphous layer 62 to embed the recessed parts 54. The conductive film 63 is formed by, for example, chemical vapor deposition (CVD). Alternatively, the conductive film 63 may be formed by atomic layer deposition (ALD). The thickness of the conductive film 63 in the Z direction is, for example, 20 nm to 100 nm. With CVD deposition technologies, the particle size of a deposited film is affected by the particle size of an underlayer in some cases. The conductive film 63, which is formed on the amorphous layer 62, is not affected by the relatively small particle size (crystalline) of the conductive film 61, and thus the particle size of the conductive film 63 can be increased.

In FIG. 1D, the amorphous layer 62 is absent. This is thought to be because of reduction of the amorphous layer 62 during formation of the conductive film 63. Part of the amorphous layer 62 may remain between the conductive films 61 and 63. The conductive film 61 and the amorphous layer 62 function as an underlayer containing tungsten for the conductive film 63.

In FIG. 1D, any excess conductive films 61 and 63 are removed up to the upper surface of the insulating film 50 by chemical mechanical polishing (CMP) or the like.

Through the processes in FIGS. 1A to 1D, the wires 70 disposed in the insulating film 50 are formed. Each wire 70 includes the electric conductors 71 and 72.

The electric conductor 71 contains tungsten.

The electric conductor 72 is provided between both the side surface and bottom surface of the electric conductor 71 and the insulating film 50. The electric conductor 72 contains tungsten.

The particle size of the electric conductor 71 is larger than the particle size of the electric conductor 72. A particle size means the size of a crystal particle and can be measured by, for example, electron backscatter diffraction (EBSD). The particle size of the electric conductor 71 is, for example, equal to or larger than 80 nm. The particle size of the electric conductor 72 is, for example, equal to or smaller than 15 nm.

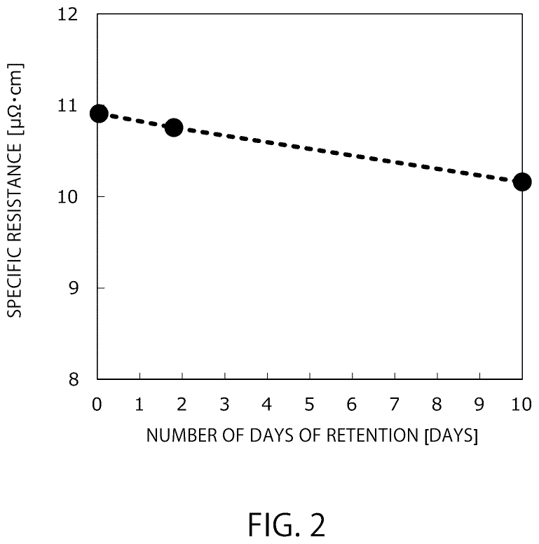

FIG. 2 is a graph illustrating an exemplary measurement result of the specific resistance of the conductive film 63 according to the first embodiment. The vertical axis represents the specific resistance (μΩ·cm) of the conductive film 63. The horizontal axis represents the number of days of retention (days) from formation of the conductive film 61 to formation of the conductive film 63. Typically, the amount of a natural oxide film on the conductive film 61 increases as the number of days of retention (days) increases.

As illustrated in FIG. 2, the specific resistance of the conductive film 63 decreases as the number of days of retention increases. The specific resistance of the conductive film 63 when the number of days of retention is 10 is smaller by approximately 10% than the specific resistance of the conductive film 63 when the number of days of retention is zero. In other words, the specific resistance of the conductive film 63 is reduced as the amorphous layer 62 is further formed by natural oxidation.

As described above, according to the first embodiment, the conductive film 61 containing tungsten is formed on the inner side surface and bottom surface of each recessed part 54. In addition, the amorphous layer 62 is formed on the conductive film 61. Furthermore, the conductive film 63 containing tungsten is formed on the amorphous layer 62 to embed the recessed parts 54. Accordingly, the particle size of the conductive film 63 can be increased, and the specific resistance of the conductive film 63 can be reduced. As a result, the resistance of each wire 70 can be reduced.

The first metal is not limited to tungsten but can also be molybdenum (Mo). In this case, the amorphous layer 62 is, for example, an oxide film layer containing molybdenum oxide (MoOₓ).

Formation of the amorphous layer 62 is not limited to natural oxidation but can also be performed by, for example, oxygen thermal treatment or oxygen plasma treatment. In this case, processes from deposition of the conductive film 61 to deposition of the conductive film 63 are performed in the same device.

Formation of the amorphous layer 62 is not limited to oxidation. The amorphous layer 62 may be formed on the surface of the conductive film 61 by ion implantation method, for example.

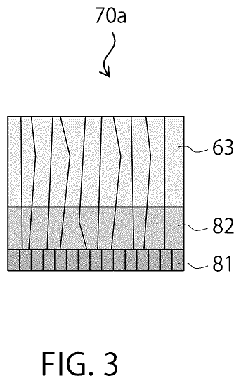

FIG. 3 is a cross sectional view illustrating an example of the configuration of a wire 70a according to a first comparative example. FIG. 3 is an enlarged cross sectional view illustrating a part of the wire 70a near a boundary with the insulating film 50, and the insulating film 50 is positioned on the lower side in FIG. 3. The first comparative example is different from the first embodiment in that a barrier metal film 81 and a nucleation layer 82 (initial layer) are formed.

In the first comparative example, the barrier metal film 81 is formed in contact with the insulating film 50 inside each recessed part 54 to enhance adhesion to the insulating film 50, for example. Thereafter, the nucleation layer 82 containing tungsten is formed on the barrier metal film 81. Thereafter, the conductive film 63 is formed on the nucleation layer 82 to embed the recessed parts 54. The barrier metal film 81 contains, for example, TIN. The resistance of the barrier metal film 81 and the nucleation layer 82 is higher than the resistance of the conductive film 63. Furthermore, the particle size of the conductive film 63 decreases due to influence of crystalline of the barrier metal film 81 and the nucleation layer 82. Smaller particle size of the conductive film 63 leads to increase in the resistance of the conductive film 63.

However, in the first embodiment, since the conductive film 61 is formed by using PVD with higher adhesion as compared to CVD, the barrier metal film 81 is unnecessary and the conductive film 63 is formed on the amorphous layer 62. The resistance of the wire 70 can be reduced by omitting the barrier metal film 81 of high resistance and suppressing decrease in the particle size of the conductive film 63. The conductive film 61 has barrier properties equivalent to those of the barrier metal film 81.

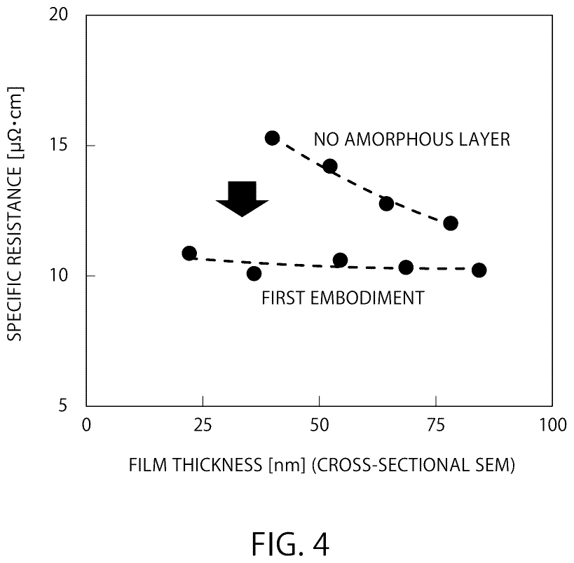

FIG. 4 is a graph illustrating an exemplary measurement result of the specific resistance of the conductive film 63 for further description of characteristics of the amorphous layer 62 in the first embodiment. The vertical axis represents specific resistance (μΩ·cm). The horizontal axis represents film thickness (nm). The film thickness is a result of cross-sectional scanning electron microscope (SEM). The value of specific resistance illustrated in FIG. 4 does not necessarily need to match the value of specific resistance illustrated in FIG. 2. This is because FIGS. 2 and 4 are verification data indicating specific resistance decrease, and film manufacturing conditions and the like are different between FIGS. 2 and 4 in some cases.

As illustrated in FIG. 4, the specific resistance of the conductive film 63 decreases in the first embodiment in which the amorphous layer 62 is formed as compared to a case where the amorphous layer 62 is not formed. This is thought to be because the particle size of the conductive film 63 increases due to the amorphous layer 62, and accordingly, the specific resistance of the conductive film 63 decreases. Thus, in the first embodiment, the resistance of the conductive film 63 can be reduced by suppressing decrease in the particle size of the conductive film 63 due to the particle size (crystalline) of the conductive film 61.

### Second Embodiment

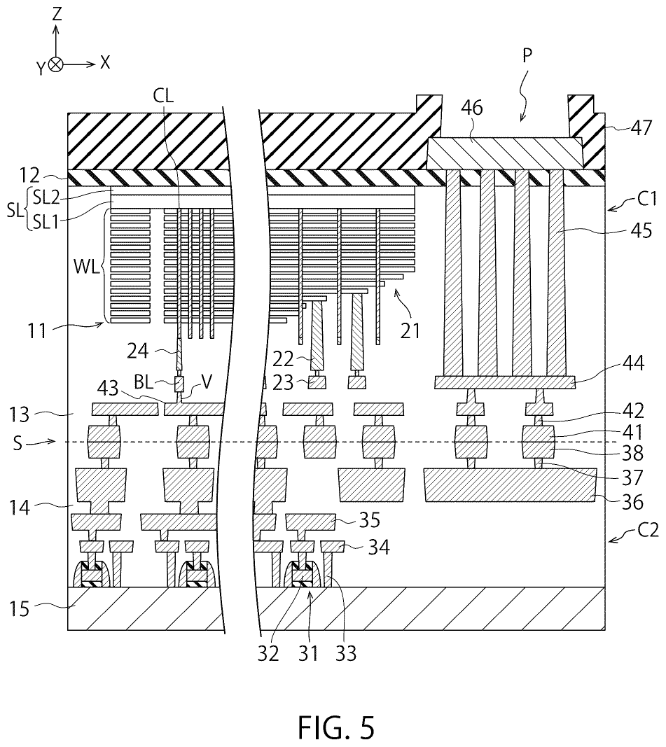

FIG. 5 is a cross sectional view illustrating an example of the structure of a semiconductor device according to a second embodiment. The semiconductor device illustrated in FIG. 5 is a three-dimensional memory with an array chip C1 and a circuit chip C2 laminated together.

The array chip C1 includes a memory cell array 11 including a plurality of three-dimensionally disposed memory cells, an insulating film 12 on the memory cell array 11, and an interlayer insulating film 13 below the memory cell array 11. The insulating film 12 is, for example, a silicon oxide film or a silicon nitride film. The interlayer insulating film 13 is, for example, a silicon oxide film or a multilayer film including a silicon oxide film and any other insulating film.

The circuit chip C2 is provided below the array chip C1. Reference sign S indicates a lamination surface of the array chip C1 and the circuit chip C2. The circuit chip C2 includes an interlayer insulating film 14 and a substrate 15 below the interlayer insulating film 14. The interlayer insulating film 14 is, for example, a silicon oxide film or a multilayer film including a silicon oxide film and any other insulating film. The substrate 15 is an example of a first substrate and is, for example, a semiconductor substrate such as a silicon substrate. FIG. 5 illustrates X and Y directions parallel to the surface of the substrate 15, in other words, the upper surface thereof and orthogonal to each other, and a Z direction orthogonal to the surface of the substrate 15. The Y direction is an example of a first direction, the X direction is an example of a second direction intersecting the first direction, and the Z direction is an example of a third direction intersecting the first and second directions.

The array chip C1 includes, as a plurality of electrode layers in the memory cell array 11, a plurality of word lines WL and a source line SL. FIG. 5 illustrates a staircase structure part 21 of the memory cell array 11. Each word line WL is electrically connected to a word wire layer 23 through a contact plug 22. A column-shaped part CL penetrating through the plurality of word lines WL is electrically connected to a bit line BL through a via plug 24 and electrically connected to the source line SL. The source line SL includes a first layer SL1 that is a semiconductor layer and a second layer SL2 that is a metal layer. Reference sign V indicates a via plug provided below the bit line BL.

The circuit chip C2 includes a plurality of transistors 31. Each transistor 31 includes a gate electrode 32 provided on the substrate 15 with a gate insulating film in between, and a source diffusion layer and a drain diffusion layer that are provided in the substrate 15 and not illustrated. The circuit chip C2 also includes a plurality of contact plugs 33 provided on the source diffusion layers or drain diffusion layers of the transistors 31, a wire layer 34 provided on the contact plugs 33 and including a plurality of wires, and a wire layer 35 provided on the wire layer 34 and including a plurality of wires.

The circuit chip C2 also includes a wire layer 36 provided on the wire layer 35 and including a plurality of wires, a plurality of via plugs 37 provided on the wire layer 36, and a plurality of metal pads 38 provided on the via plugs 37. The metal pads 38 are, for example, a copper (Cu) layer or an aluminum (Al) layer. The circuit chip C2 functions as a control circuit (logic circuit) configured to control operation of the array chip C1. The control circuit includes the transistors 31 and is electrically connected to the metal pads 38.

The array chip C1 includes a plurality of metal pads 41 provided on the metal pads 38, and a plurality of via plugs 42 provided on the metal pads 41. The array chip C1 also includes a wire layer 43 provided on the via plugs 42 and including a plurality of wires, and a wire layer 44 provided on the wire layer 43 and including a plurality of wires including the bit line BL. The metal pads 41 are, for example, a Cu layer or an Al layer. The above-described via plug V is connected to the wire layer 43 and the bit line BL.

The array chip C1 also includes a plurality of via plugs 45 provided on the wire layer 44, a metal pad 46 provided on the via plugs 45 and the insulating film 12, and a passivation film 47 provided on the metal pad 46 and the insulating film 12. The metal pad 46 is, for example, a Cu layer or an Al layer and functions as an external connection pad (bonding pad) of the semiconductor device in FIG. 5. The passivation film 47 is, for example, an insulating film such as a silicon oxide film and includes an opening part P where the upper surface of the metal pad 46 is exposed. The metal pad 46 is connectable to a mounting substrate or another device by a bonding wire, a soldering ball, a metal bump, or the like through the opening part P.

The wire 70 described above in the first embodiment corresponds to, for example, a wire in the wire layer 43. The insulating film 50 described above in the first embodiment corresponds to, for example, part of the interlayer insulating film 13. In FIG. 5, the up-down direction is inverted as compared to FIG. 1D.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device manufacturing method comprising:
forming a recessed part in a first insulating film;
forming a first conductive film containing a first metal on an inner side surface and a bottom surface of the recessed part;
forming an amorphous layer on the first conductive film; and
forming a second conductive film containing the first metal on the amorphous layer.

2. The semiconductor device manufacturing method according to claim 1, wherein
forming the amorphous layer includes oxidizing a surface of the first conductive film to form an oxide film, and
the oxide film contains an oxide of the first metal.

3. The semiconductor device manufacturing method according to claim 2, wherein oxidizing the surface of the first conductive film includes natural oxidation.

4. The semiconductor device manufacturing method according to claim 2, wherein oxidizing the surface of the first conductive film includes oxygen thermal treatment or oxygen plasma treatment.

5. The semiconductor device manufacturing method according to claim 2, wherein forming the second conductive film includes forming the second conductive film while reducing at least part of the oxide film.

6. The semiconductor device manufacturing method according to claim 1, wherein the amorphous layer is thinner than the first conductive film.

7. The semiconductor device manufacturing method according to claim 2, wherein the amorphous layer is thinner than the first conductive film.

8. The semiconductor device manufacturing method according to claim 1, wherein
forming the first conductive film includes forming the first conductive film by physical vapor deposition (PVD), and
forming the second conductive film includes forming the second conductive film by chemical vapor deposition (CVD) or atomic layer deposition (ALD).

9. The semiconductor device manufacturing method according to claim 2, wherein
forming the first conductive film includes forming the first conductive film by physical vapor deposition (PVD), and
forming the second conductive film includes forming the second conductive film by chemical vapor deposition (CVD) or atomic layer deposition (ALD).

10. The semiconductor device manufacturing method according to claim 1, wherein the first metal is tungsten (W) or molybdenum (Mo).

11. The semiconductor device manufacturing method according to claim 2, wherein the first metal is tungsten (W) or molybdenum (Mo).

12. A semiconductor device comprising:
a first insulating film; and
a wire disposed on the first insulating film, wherein
the wire includes
a first electric conductor containing a first metal, and
a second electric conductor containing the first metal and provided between both a side surface and a bottom surface of the first electric conductor and the first insulating film, and
the first electric conductor has a particle size equal to or larger than 80 nm.

13. The semiconductor device according to claim 12, wherein the particle size of the first electric conductor is larger than a particle size of the second electric conductor.

14. The semiconductor device according to claim 12, wherein the first metal is tungsten (W) or molybdenum (Mo).

15. The semiconductor device according to claim 13, wherein the first metal is tungsten (W) or molybdenum (Mo).
